(19) United States
(12) Patent Application Publication
(10) Pub. No.: US 2025/0359232 A1
(43) Pub. Date: Nov. 20, 2025

(54) NITRIDE SEMICONDUCTOR DEVICE AND METHOD FOR MANUFACTURING NITRIDE SEMICONDUCTOR DEVICE

(71) Applicant: SUMITOMO ELECTRIC INDUSTRIES, LTD., Osaka (JP)

(72) Inventor: Daiki TAKAYAMA, Osaka (JP)

(21) Appl. No.: 19/205,192

(22) Filed: May 12, 2025

(30) Foreign Application Priority Data
May 15, 2024 (JP) 2024-079117

(51) Int. Cl. H10D 62/13; H10D 30/01; H10D 30/47; H10D 62/85

(52) U.S. Cl. CPC H10D 62/161; H10D 30/015; H10D 30/475; H10D 62/8503

(57) ABSTRACT

A nitride semiconductor device includes a first nitride semiconductor layer including a channel layer and a barrier layer, a second nitride semiconductor layer, and a third nitride semiconductor layer. The channel layer and the barrier layer are interposed between the second nitride semiconductor layer and the third nitride semiconductor layer. In a cross-sectional view including a first axis and a second axis, the second nitride semiconductor layer includes a first covering portion covering a portion of a third surface of an insulating layer, and the third nitride semiconductor layer includes a second covering portion covering a portion of the third surface.

### CROSS-REFERENCE TO RELATED APPLICATION

This application claims priority under 35 U.S.C. § 119 to Japanese Patent Application No. 2024-079117, filed May 15, 2024, the contents of which are incorporated herein by reference.

### BACKGROUND

### 1. Technical Field

The present disclosure relates to a nitride semiconductor device and a method for manufacturing the nitride semiconductor device.

### 2. Description of the Related Art

In order to reduce the contact resistance or the like in nitride semiconductor devices, a structure in which a nitride semiconductor layer containing impurities at high concentration is regrown has been proposed.

### RELATED-ART DOCUMENT

Patent Document 1: Japanese Unexamined Patent Application Publication No. 2007-329350

Patent Document 2: Japanese Unexamined Patent Application Publication No. 2007-538402

### SUMMARY

A nitride semiconductor device in the present disclosure includes a first nitride semiconductor layer including a channel layer and a barrier layer that overlap along a first axis, the first nitride semiconductor layer having a first surface intersecting the first axis; an insulating layer provided on the first surface, and having a second surface facing the first surface and a third surface opposite the second surface; a second nitride semiconductor layer; and a third nitride semiconductor layer. The channel layer and the barrier layer are interposed between the second nitride semiconductor layer and the third nitride semiconductor layer along a second axis intersecting the first axis, and in a cross-sectional view including the first axis and the second axis, the second nitride semiconductor layer includes a first covering portion covering a portion of the third surface, and the third nitride semiconductor layer includes a second covering portion covering a portion of the third surface.

In the present disclosure, high breakdown voltage can be obtained.

### BRIEF DESCRIPTION OF THE DRAWINGS

FIG. 1 is a cross-sectional view showing a nitride semiconductor device according to an embodiment.

FIG. 2 is a plan view showing the nitride semiconductor device according to the embodiment.

FIG. 3 is a cross-sectional view (part 1) showing a method for manufacturing the nitride semiconductor device according to the embodiment.

FIG. 4 is a cross-sectional view (part 2) showing the method for manufacturing the nitride semiconductor device according to the embodiment.

FIG. 5 is a cross-sectional view (part 3) showing the method for manufacturing the nitride semiconductor device according to an embodiment.

FIG. 6 is a cross-sectional view (part 4) showing the method for manufacturing the nitride semiconductor device according to the embodiment.

FIG. 7 is a cross-sectional view (part 5) showing the method for manufacturing the nitride semiconductor device according to the embodiment.

FIG. 8 is a cross-sectional view (part 6) showing the method for manufacturing the nitride semiconductor device according to the embodiment.

FIG. 9 is a cross-sectional view (part 7) showing the method for manufacturing the nitride semiconductor device according to the embodiment.

FIG. 10 is a cross-sectional view (part 8) showing the method for manufacturing the nitride semiconductor device according to the embodiment.

FIG. 11 is a cross-sectional view (part 9) showing the method for manufacturing the nitride semiconductor device according to the embodiment.

FIG. 12 is a cross-sectional view (part 10) showing the method for manufacturing the nitride semiconductor device according to the embodiment.

FIG. 13 is a cross-sectional view (part 11) showing the method for manufacturing the nitride semiconductor device according to the embodiment.

FIG. 14 is a cross-sectional view (part 12) showing the method for manufacturing the nitride semiconductor device according to the embodiment.

### DETAILED DESCRIPTION

In recent years, there has been an increasing demand for further improvement in breakdown voltage.

An object of the present disclosure is to provide a nitride semiconductor device and a method for manufacturing the nitride semiconductor device that has high breakdown voltage.

First, embodiments of the present disclosure will be listed and described.
[1] A nitride semiconductor device according to one aspect of the present disclosure includes a first nitride semiconductor layer including a channel layer and a barrier layer that overlap along a first axis, the first nitride semiconductor layer having a first surface intersecting the first axis; an insulating layer provided on the first surface, and having a second surface facing the first surface and a third surface opposite the second surface; a second nitride semiconductor layer; and a third nitride semiconductor layer. The channel layer and the barrier layer are interposed between the second nitride semiconductor layer and the third nitride semiconductor layer along a second axis intersecting the first axis. In a cross-sectional view including the first axis and the second axis, the second nitride semiconductor layer includes a first covering portion covering a portion of the third surface, and the third nitride semiconductor layer includes a second covering portion covering a portion of the third surface.

When a second nitride semiconductor layer and a third nitride semiconductor layer are formed, an unnecessary nitride semiconductor layer including polycrystalline material is formed on a third surface. The second nitride semiconductor layer includes a first covering portion, and the third nitride semiconductor layer includes a second covering portion. In this arrangement, the etchant does not contact the first nitride semiconductor layer when removing the unnecessary nitride semiconductor layer. As a result, a barrier layer and a channel layer are not etched, and high breakdown voltage is obtained in a nitride semiconductor device.
[2] In [1], a first nitride semiconductor layer has a fourth surface opposite a first surface, and a first covering portion may have a fifth surface disposed at a distance from the fourth surface that is greater than a reference distance between the first surface and the fourth surface. A second covering portion may have a sixth surface disposed at a distance from the fourth surface that is greater than the reference distance. In this case, etching of a barrier layer and a channel layer can be easily prevented.
[3] In [2], a distance between a third surface and a fifth surface may be greater than or equal to 10 nm and less than or equal to 100 nm, and a distance between the third surface and a sixth surface may be greater than or equal to 10 nm and less than or equal to 100 nm. When these distances are 10 nm or more, etching of a barrier layer and a channel layer can be more easily prevented. When these distances are 100 nm or less, excessive steps can be easily prevented.
[4] In any one of [1] to [3], a first covering portion and a second covering portion may include polycrystalline material. Even when the first covering portion and the second covering portion include polycrystalline material, etching of a barrier layer and a channel layer can be prevented.
[5] In any one of [1] to [4], a first nitride semiconductor layer may include a cap layer having the first surface. In this case, a barrier layer can be protected from damage such as plasma that is generated in a manufacturing process of a nitride semiconductor device.
[6] In any one of [1] to [5], a length of a first covering portion in a direction along a second axis may be greater than or equal to 50 nm and less than or equal to 300 nm, and a length of a second covering portion in a direction along the second axis may be greater than or equal to 50 nm and less than or equal to 300 nm. When the above lengths are 50 nm or greater, etching of a barrier layer and a channel layer can be prevented more easily. When these lengths are 300 nm or less, short-circuiting between a gate electrode and each of a second nitride semiconductor layer and a third nitride semiconductor layer can be easily prevented. Here, the gate electrode is provided between the second nitride semiconductor layer and the third nitride semiconductor layer.
[7] In any one of [1] to [6], a channel layer may include a channel region including two-dimensional electron gas, and electrical resistance of a second nitride semiconductor layer and electrical resistance of a third nitride semiconductor layer may be both lower than electrical resistance of the channel region. In this case, the electrical resistance between electrodes provided on the second nitride semiconductor layer and the third nitride semiconductor layer can be reduced.
[8] In any one of [1] to [7], a second nitride semiconductor layer and a third nitride semiconductor layer may include an n-type impurity. In this case, low electrical resistance for the second nitride semiconductor layer and the third nitride semiconductor layer can be easily obtained.
[9] In [8], concentration of an impurity may be 1×10²⁰ cm⁻³ or more. In this case, particularly low electrical resistance for each of a second nitride semiconductor layer and a third nitride semiconductor layer can be easily obtained.
[10] In any one of [1] to [9], a first nitride semiconductor layer may include a first recess and a second recess such that a channel layer and a barrier layer are interposed between the first recess and the second recess along a second axis. A second nitride semiconductor layer may be provided in the first recess, and a third nitride semiconductor layer may be provided in the second recess. In this case, the second nitride semiconductor layer and the third nitride semiconductor layer can be easily formed.
[11] A method for manufacturing a nitride semiconductor device according to another aspect of the present disclosure includes providing a first nitride semiconductor layer including a channel layer and a barrier layer that overlap along a first axis, the first nitride semiconductor layer having a first surface; forming, on the first surface, a first insulating layer having a second surface facing the first surface and a third surface opposite the second surface; forming a first opening and a second opening in the first insulating layer, such that the channel layer and the barrier layer are interposed between the first opening and the second opening along a second axis intersecting the first axis, in a plan view; forming, in the first nitride semiconductor layer, a first recess connected to the first opening, and a second recess connected to the second opening; forming, by sputtering, a fourth nitride semiconductor layer in the first recess and the first opening, in the second recess and the second opening, and on the first insulating layer, the fourth nitride semiconductor layer including polycrystalline material on the first insulating layer; forming, on the fourth nitride semiconductor layer, a second insulating layer covering both a portion of the fourth nitride semiconductor layer in the first recess and the first opening, and a portion of the fourth nitride semiconductor layer located on a portion of the first insulating layer, and a third insulating layer covering both a portion of the fourth nitride semiconductor layer in the second recess and the second opening, and a portion of the fourth nitride semiconductor layer located on a portion of the first insulating layer; and removing a portion of the fourth nitride semiconductor layer that is not covered by the second insulating layer and the third insulating layer to form: a second nitride semiconductor layer including a first covering portion covering a portion of the third surface, and a third nitride semiconductor layer including a second covering portion covering a portion of the third surface.

With this approach, when removing an unnecessary nitride semiconductor layer, the etchant does not contact a first nitride semiconductor layer. In this case, a barrier layer and a channel layer are not etched, and high breakdown voltage for a nitride semiconductor device is obtained.

### Details of Embodiments of the Present Disclosure

Embodiments of the present disclosure will be described in detail below, but the present disclosure is not limited to the embodiments. In this description and the drawings, duplicate description for components having substantially the same functional configuration may be omitted by using the same reference numerals. In the following description, an XYZ Cartesian coordinate system is used, but the coordinate system is specified for the purpose of explanation, and does not limit the orientation of a nitride semiconductor device. Further, an XY plane view is called a plan view, and from any given point, the +Z direction may be referred to as upward direction, upper side, or up, and the −Z direction may be downward direction, lower side, or down.

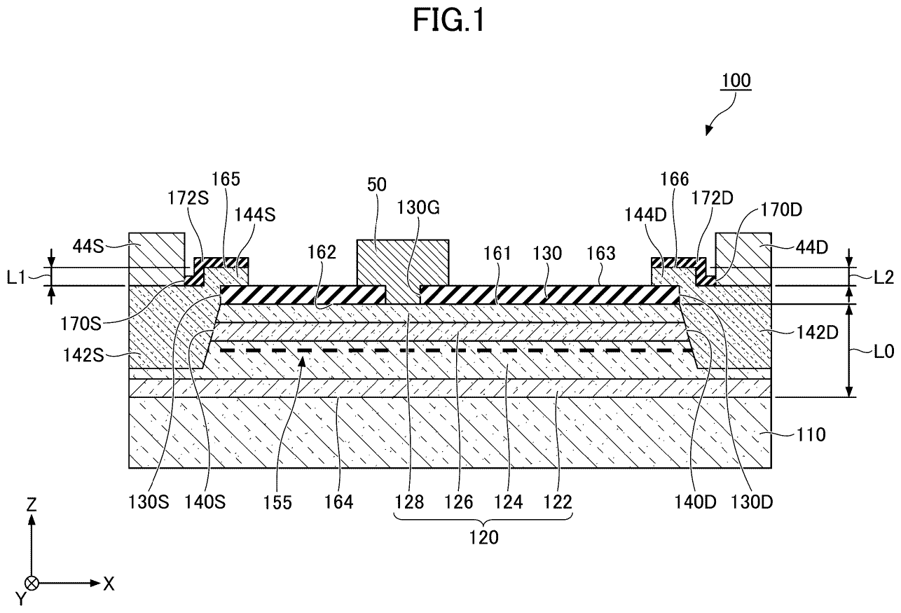

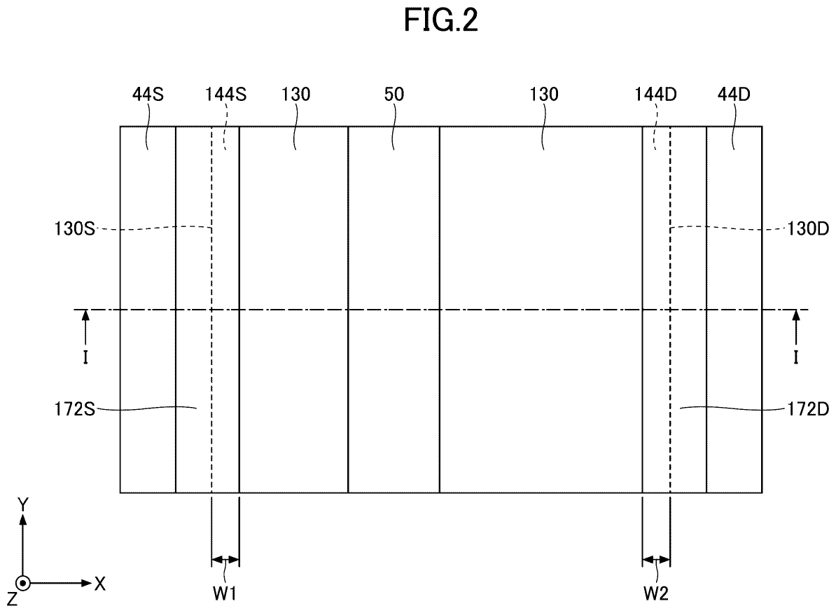

One or more embodiments of the present disclosure relate to a nitride semiconductor device including a high electron mobility transistor (HEMT). FIG. 1 is a cross-sectional view showing the nitride semiconductor device according to the embodiment. FIG. 2 is a plan view showing the nitride semiconductor device according to the embodiment. FIG. 1 corresponds to a cross-sectional view taken along the line I-I in FIG. 2.

As shown in FIGS. 1 and 2, a nitride semiconductor device 100 according to the embodiment includes a substrate 110, a first nitride semiconductor layer 120, a second nitride semiconductor layer 142S, a third nitride semiconductor layer 142D, an insulating layer 130, a gate electrode 50, a source electrode 44S, a drain electrode 44D, an insulating layer 172S, and an insulating layer 172D.

The substrate 110 is, for example, a substrate for growing a gallium nitride (GaN)-based semiconductor layer, and is, for example, a semi-insulating silicon carbide (Sic) substrate. When the substrate 110 is the

SiC substrate, the upper surface of the substrate 110 is a silicon (Si) polar surface. When the surface of the substrate 110 is the Si-polar surface, the first nitride semiconductor layer 120 is crystal-grown using a gallium (Ga) polar surface as a growth surface.

The first nitride semiconductor layer 120 has a buffer layer 122, a channel layer 124, a barrier layer 126, and a cap layer 128. The buffer layer 122, the channel layer 124, the barrier layer 126, and the cap layer 128 overlap in this order along the Z-axis. The first nitride semiconductor layer 120 has an upper surface 161 and a lower surface 164 that intersect with the Z-axis. The cap layer 128 has the upper surface 161. The Z-axis is an example of a first axis. The upper surface 161 is an example of a first surface, and the lower surface 164 is an example of a fourth surface opposite the first surface.

The buffer layer 122 is disposed on the substrate 110. The buffer layer 122 is, for example, an aluminum nitride (AlN) layer. The buffer layer 122 may have an AlN layer and either a GaN layer or an aluminum gallium nitride (AlGaN) layer, on the AlN layer. The channel layer 124 is disposed on the buffer layer 122. The channel layer 124 is, for example, an undoped gallium nitride (GaN) layer. The barrier layer 126 is disposed on the channel layer 124. The barrier layer 126 is, for example, an n-type AlGAN layer. A channel region 155 containing two-dimensional electron gas (2DEG) exists in proximity to the upper surface of the channel layer 124. The cap layer 128 is disposed on the barrier layer 126. The cap layer 128 is, for example, an n-type GaN layer.

A first recess 140S for a source and a second recess 140D for a drain are formed in the cap layer 128, the barrier layer 126, and a portion of the channel layer 124. The first recess 140S and the second recess 140D penetrate through the cap layer 128 and the barrier layer 126 along the Z-axis, and enter into the channel layer 124. The channel layer 124 is exposed through the first recess 140S and the second recess 140D.

The insulating layer 130 is disposed on the cap layer 128. The insulating layer 130 is, for example, a silicon nitride (SiN) film. The thickness of the insulating layer 130 is, for example, greater than or equal to 1 nm and less than or equal to 20 nm. The insulating layer 130 has an upper surface 163 and a lower surface 162 that intersect with the Z-axis. An opening 130S for the source and an opening 130D for the drain are formed in the insulating layer 130. The opening 130S is connected to the first recess 140S, and the opening 130D is connected to the second recess 140D. The opening 130D is located on the +X side of the opening 130S. The lower surface 162 is an example of a second surface, and the upper surface 163 is an example of a third surface opposite the second surface. The X-axis is an example of a second axis.

The second nitride semiconductor layer 142S is disposed on the channel layer 124 in the first recess 140S and the opening 130S. In a ZX sectional view including the Z-axis and the X-axis, the second nitride semiconductor layer 142S has a first covering portion 144S covering a portion of the upper surface 163. The first covering portion 144S may have polycrystalline material. The first covering portion 144S has an upper surface 165. A distance of the upper surface 165 from the lower surface 164 of the first nitride semiconductor layer 120 may be greater than a reference distance L0 between the upper surface 161 and the lower surface 164 of the first nitride semiconductor layer 120. When a distance between the upper surface 161 and the lower surface 164 varies depending on the flatness of the upper surface 161 and the lower surface 164, depending on the position in the X-axis direction and the position in the Y-axis direction, the reference distance L0 may be set as a maximum value estimated from distance values that are obtained at respective different positions. For example, when the flatness of both the upper surface 161 and the lower surface 164 is good, and a difference between an average value, and the maximum value, of the distances obtained at the respective different positions is 0.5 nm or less, the reference distance L0 may be set as the average value. The second nitride semiconductor layer 142S contacts the sidewall surface of the opening 130S and the sidewall surface of the first recess 140S. The upper surface 165 is an example of a fifth surface.

The third nitride semiconductor layer 142D is disposed on the channel layer 124 in the second recess 140D and the opening 130D. In a ZX cross-sectional view including the Z-axis and the X-axis, the third nitride semiconductor layer 142D has a second covering portion 144D covering a portion of the upper surface 163. The second covering portion 144D may have polycrystalline material. The second covering portion 144D has an upper surface 166. A distance of the upper surface 166 from the lower surface 164 of the first nitride semiconductor layer 120 may be greater than the reference distance L0 between the upper surface 161 and the lower surface 164 of the first nitride semiconductor layer 120. The third nitride semiconductor layer 142D contacts the sidewall surface of the opening 130D and the sidewall surface of the second recess 140D. The upper surface 166 is an example of a sixth surface.

The second nitride semiconductor layer 142S and the third nitride semiconductor layer 142D are disposed so as to interpose a portion of the channel layer 124 and the barrier layer 126 between these layers along the X-axis. The second nitride semiconductor layer 142S and the third nitride semiconductor layer 142D are n-type GaN layers, for example. The electrical resistance of the second nitride semiconductor layer 142S and the third nitride semiconductor layer 142D is lower than that of the channel region 155.

The insulating layer 172S is disposed on the second nitride semiconductor layer 142S. The insulating layer 172S covers the upper surface 165 of the first covering portion 144S. The insulating layer 172D is disposed on the third nitride semiconductor layer 142D. The insulating layer 172D covers the upper surface 166 of the second covering portion 144D. The insulating layers 172S and 172D are, for example, silicon nitride (SiN) films. The thickness of each of the insulating layers 172S and 172D is, for example, greater than or equal to 5 nm and less than or equal to 20 nm. An opening 170S for the source is formed in the insulating layer 172S. The opening 170S reaches the second nitride semiconductor layer 142S. That is, the second nitride semiconductor layer 142S is exposed through the opening 170S. An opening 170D for the drain is formed in the insulating layer 172D. The opening 170D reaches the third nitride semiconductor layer 142D. That is, the third nitride semiconductor layer 142D is exposed through the opening 170D. For example, the opening 170S is separated from the first covering portion 144S, and the opening 170D is separated from the second covering portion 144D.

The source electrode 44S is disposed on the second nitride semiconductor layer 142S inside the opening 170S, and the drain electrode 44D is disposed on the third nitride semiconductor layer 142D inside the opening 170D. The source electrode 44S directly contacts the second nitride semiconductor layer 142S, and the drain electrode 44D directly contacts the third nitride semiconductor layer 142D. The source electrode 44S is in ohmic contact with the second nitride semiconductor layer 142S, and the drain electrode 44D is in ohmic contact with the third nitride semiconductor layer 142D.

An opening 130G for a gate is formed in the insulating layer 130. The opening 130G is located between the opening 130S and the opening 130D along the X-axis. A gate electrode 50 is provided on the insulating layer 130 and is in Schottky contact with the first nitride semiconductor layer 120 through the opening 130G. In accordance with a voltage applied to the gate electrode 50, the current that flows between the drain electrode 44D and the source electrode 44S via the channel region 155 changes.

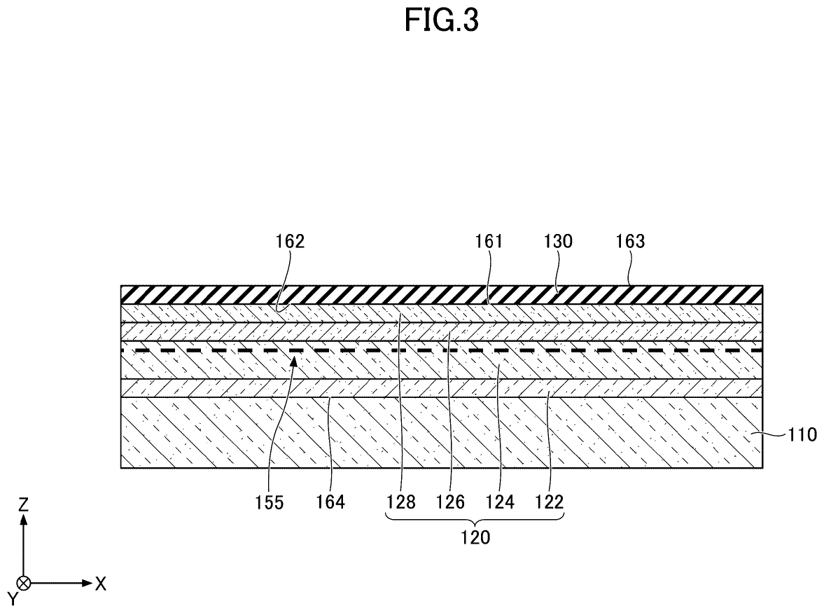

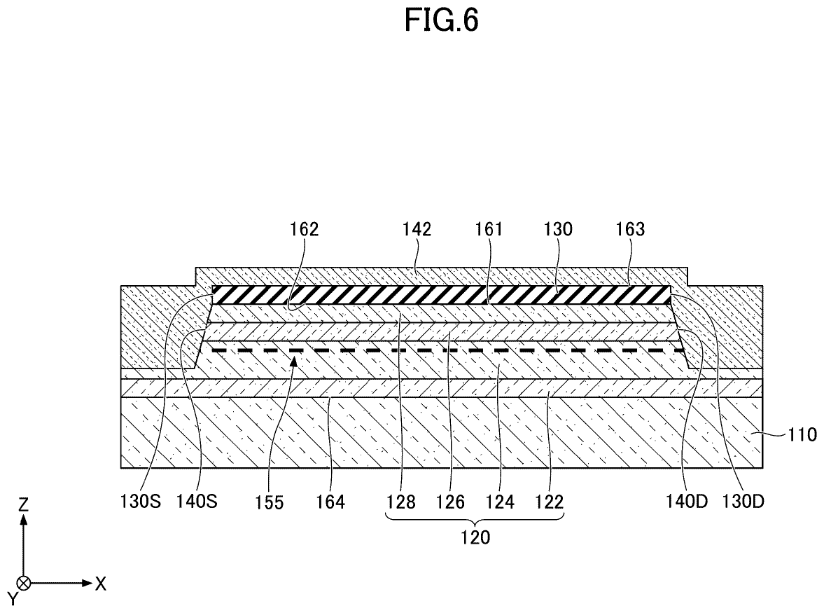

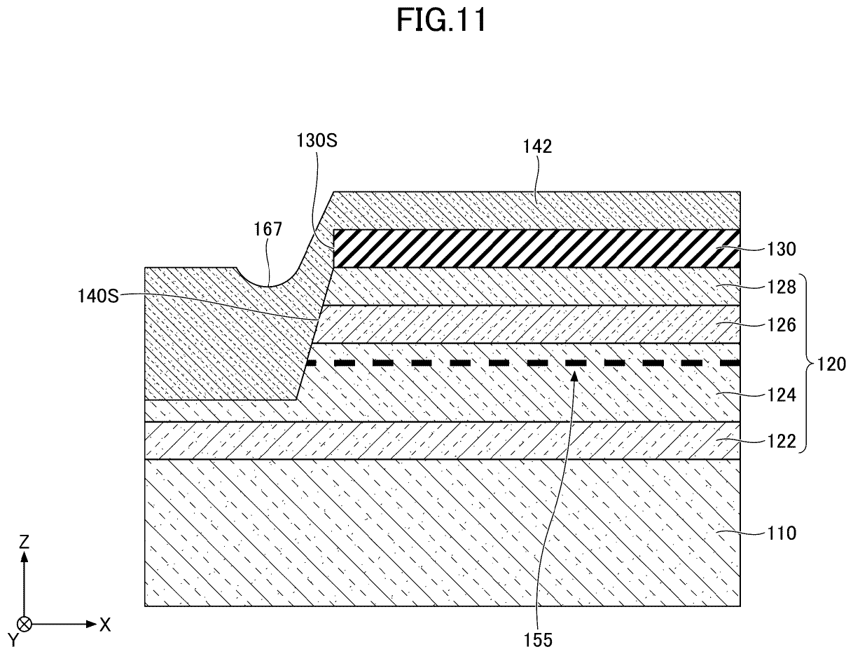

Hereinafter, a method for manufacturing the nitride semiconductor device 100 according to the embodiment will be described. FIGS. 3 to 14 are cross-sectional views showing the method for manufacturing the nitride semiconductor device 100 according to the embodiment. FIGS. 11 to 14 show enlarged portions of FIGS. 6 to 9, respectively.

As shown in FIG. 3, the buffer layer 122, the channel layer 124, the barrier layer 126, and the cap layer 128 are first formed on and above the substrate 110. The buffer layer 122, the channel layer 124, the barrier layer 126, and the cap layer 128 can be formed by, for example, metalorganic chemical vapor deposition (MOCVD). Next, the insulating layer 130 is formed on the cap layer 128. The insulating layer 130 can be formed by, for example, chemical vapor deposition (CVD). With this approach, the first nitride semiconductor layer 120 is obtained. The insulating layer 130 is an example of a first insulating layer.

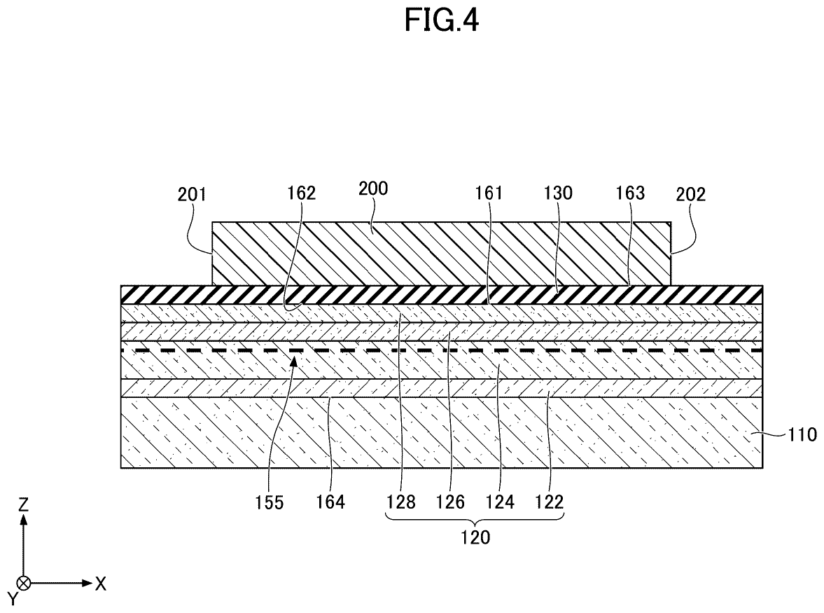

Next, as shown in FIG. 4, a mask 200 is formed on the insulating layer 130. The mask 200 has an opening 201 for the first recess 140S and an opening 202 for the second recess 140D. For example, the mask 200 is formed using photoresist.

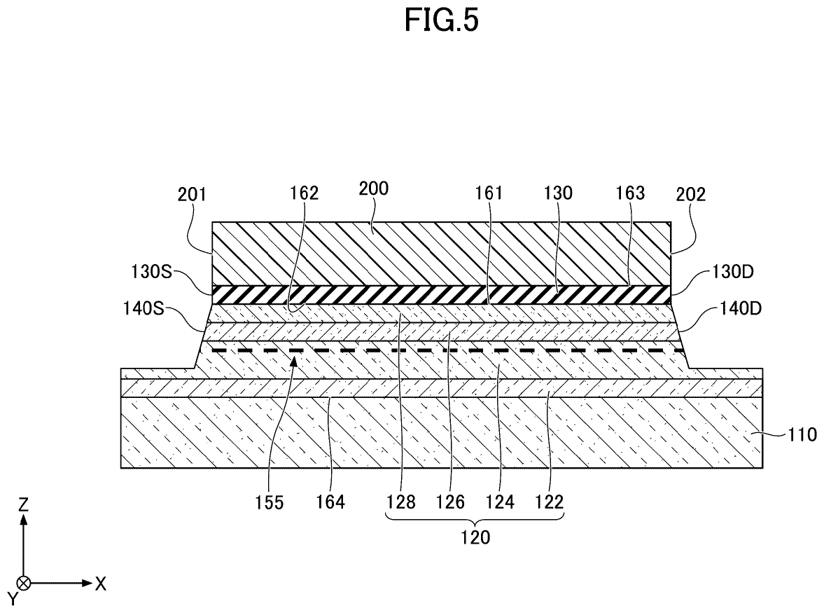

Next, as shown in FIG. 5, the insulating layer 130 is etched through the opening 201 and the opening 202 to form both an opening 130S connected to the opening 201 and an opening 130D connected to the opening 202 in the insulating layer 130. For example, the etching of the insulating layer 130 is performed under conditions where side etching is unlikely to occur. In a plan view along the Z-axis, the opening 130S is formed to have the same size as the opening 201, and the opening 130D is formed to have the same size as the opening 202. For example, in the X-axis direction, the +X-side edge of the opening 130S coincides with the +X-side edge of the opening 201, and the −X-side edge of the opening 130D coincides with the −X-side edge of the opening 202. However, it is not necessary that these edges coincide completely, and manufacturing errors or predetermined offsets may be preset. The opening 130S and the opening 130D can be formed by reactive ion etching (RIE) using, for example, a reactive gas that contains fluorine (F). The opening 130S is an example of a first opening, and the opening 130D is an example of a second opening.

Next, the first nitride semiconductor layer 120 is etched through the openings 201 and 202 to form both a first recess 140S connected to the opening 130S and a second recess 140D connected to the opening 130D in the first nitride semiconductor layer 120. The first recess 140S and the second recess 140D are formed to interpose a portion of the channel layer 124 and the barrier layer 126 between these recesses along the X-axis. The first recess 140S and the second recess 140D can be formed, for example, by RIE using a reactive gas containing chlorine (Cl). For example, angles between sidewall surfaces of the first recess 140S and the second recess 140D, and the upper surface 161 of the first nitride semiconductor layer 120, are made to be close to 90 degrees. In the ZX cross-section shown in FIG. 5, an angle formed between sidewall surface of the first recess 140S and the upper surface 161 of the first nitride semiconductor layer 120, and an angle formed between the sidewall surface of the second recess 140D and the upper surface 161 of the first nitride semiconductor layer 120 may be greater than 90 degrees, respectively.

Next, as shown in FIG. 6, the mask 200 is removed. Then, the fourth nitride semiconductor layer 142, which will become the second nitride semiconductor layer 142S and the third nitride semiconductor layer 142D, is formed. The fourth nitride semiconductor layer 142 can be formed by, for example, sputtering. When the fourth nitride semiconductor layer 142 is formed by sputtering, the supply of Ga and the supply of n-type impurities may be intermittently performed while continuously supplying nitrogen radicals. The fourth nitride semiconductor layer 142 is formed in the first recess 140S and the opening 130S, in the second recess 140D and the opening 130D, and on the insulating layer 130. A portion of the fourth nitride semiconductor layer 142 in the first recess 140S and the opening 130S is epitaxially grown and includes single crystal. A portion of the fourth nitride semiconductor layer 142 in the second recess 140D and the opening 130D is also epitaxially grown and includes single crystal. The fourth nitride semiconductor layer 142 contacts the channel layer 124 at bottoms of the first recess 140S and the second recess 140D. On the other hand, a portion of the fourth nitride semiconductor layer 142 on the insulating layer 130 does not grow epitaxially and has polycrystalline material.

When the fourth nitride semiconductor layer 142 is formed by sputtering, as shown in FIG. 11, a recess 167 may be formed on the upper surface of the fourth nitride semiconductor layer 142, in proximity to the sidewall surface of the opening 130S. Similarly, a recess 167 may be formed on the upper surface of the fourth nitride semiconductor layer 142, in proximity to the sidewall surface of the opening 130D. This is because a portion of the flow of source material flying from a target is blocked by the fourth nitride semiconductor layer 142 that has already been formed on the insulating layer 130. Also, the shape and size of the recess 167 in the ZX cross-sectional view become non-uniform along the Y-axis direction.

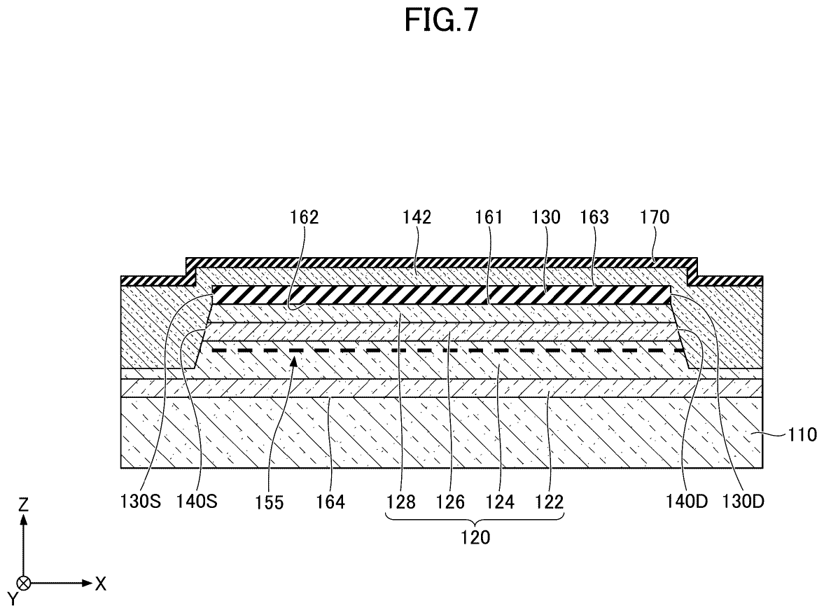

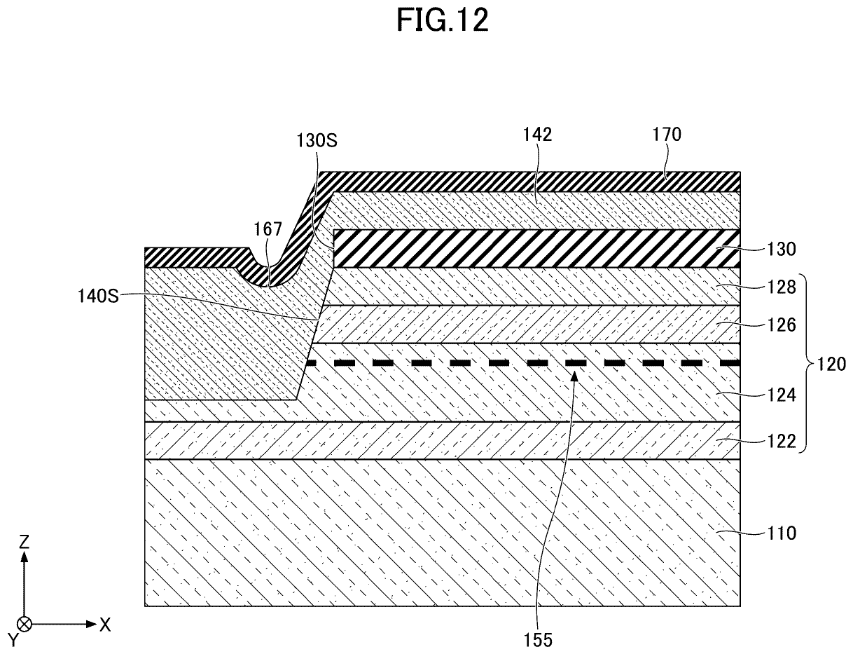

Next, as shown in FIGS. 7 and 12, an insulating layer 170 is formed on the fourth nitride semiconductor layer 142. The insulating layer 170 can be formed by, for example, CVD. The insulating layer 170 covers the recess 167.

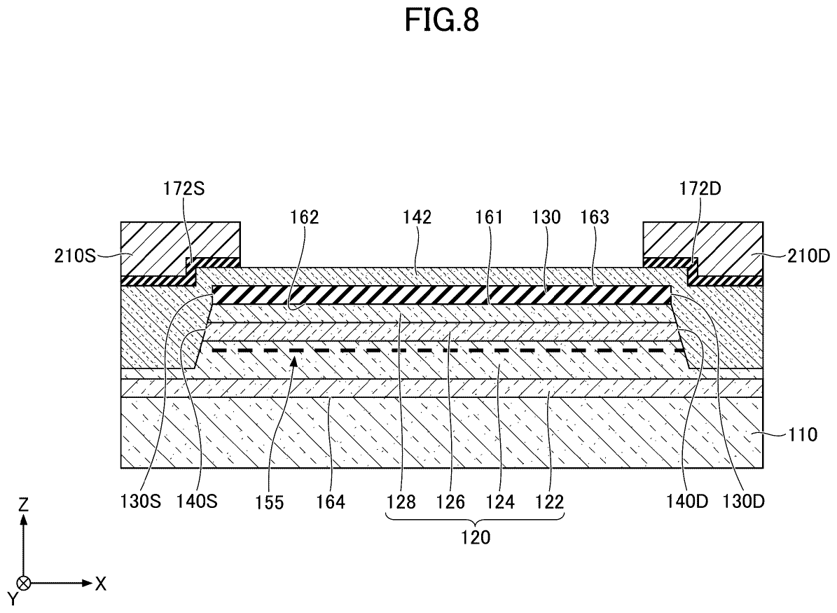

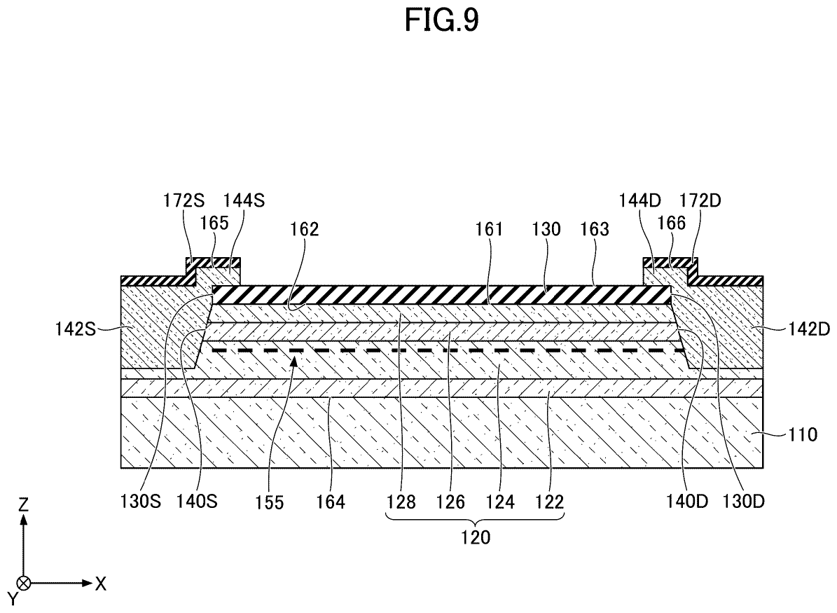

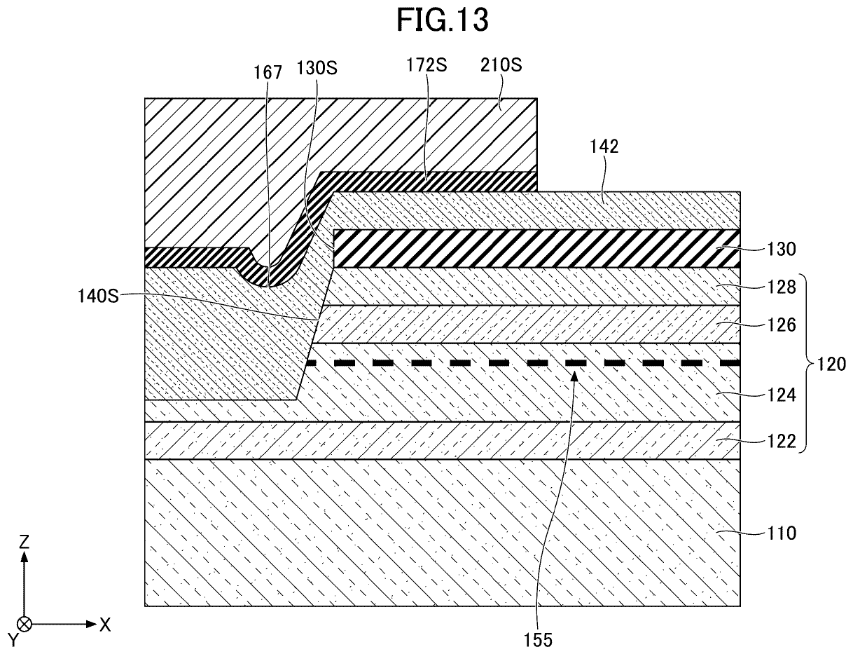

Next, as shown in FIGS. 8 and 13, a mask 210S and a mask 210D are formed on the insulating layer 170. The mask 210S covers a region where the insulating layer 172S is to be formed, and the mask 210D covers a region where the insulating layer 172D is to be formed. The mask 210S covers at least the −X side edge of the cap layer 128, and the mask 210D covers at least the +X side edge of the cap layer 128. For example, the mask 210S and the mask 210D are formed using photoresist. For example, by removing portions other than the mask 210S and the mask 210D through patterning of the photoresist that is uniformly formed on the insulating layer 170, the mask 210S and the mask 210D are formed. Then, portions of the insulating layer 170 exposed outside the mask 210S and the mask 210D are etched to form the insulating layer 172S and the insulating layer 172D from the insulating layer 170. The insulating layer 172S covers both a portion of the fourth nitride semiconductor layer 142 in the first recess 140S and the opening 130S, and a portion of the fourth nitride semiconductor layer 142 located on a portion of the insulating layer 130. The insulating layer 172D covers both a portion of the fourth nitride semiconductor layer 142 in the second recess 140D and the opening 130D, and a portion of the fourth nitride semiconductor layer 142 located on a portion of the insulating layer 130. The insulating layer 170 is etched by, for example, RIE using a reactive gas containing fluorine (F). The insulating layer 170 may be etched by wet etching using buffered hydrofluoric acid. The insulating layer 172S is an example of a second insulating layer, and the insulating layer 172D is an example of a third insulating layer. Next, as shown in FIG. 9, the mask 210S and the

mask 210D are removed. Then, a portion of the fourth nitride semiconductor layer 142 exposed outside the insulating layer 172S and the insulating layer 172D is removed to form a second nitride semiconductor layer 142S and a third nitride semiconductor layer 142D from the fourth nitride semiconductor layer 142. The second nitride semiconductor layer 142S has a first covering portion 144S covering a portion of the upper surface 163, and the third nitride semiconductor layer 142D has a second covering portion 144D covering a portion of the upper surface 163. The portion of the fourth nitride semiconductor layer 142 exposed outside the insulating layer 172S and the insulating layer 172D contain the polycrystalline material as described above. This portion can be removed by using an alkaline etchant such as tetramethylammonium hydroxide (TMAH). The temperature of the TMAH is, for example, greater than or equal to 70° C. and less than or equal to 80° C.

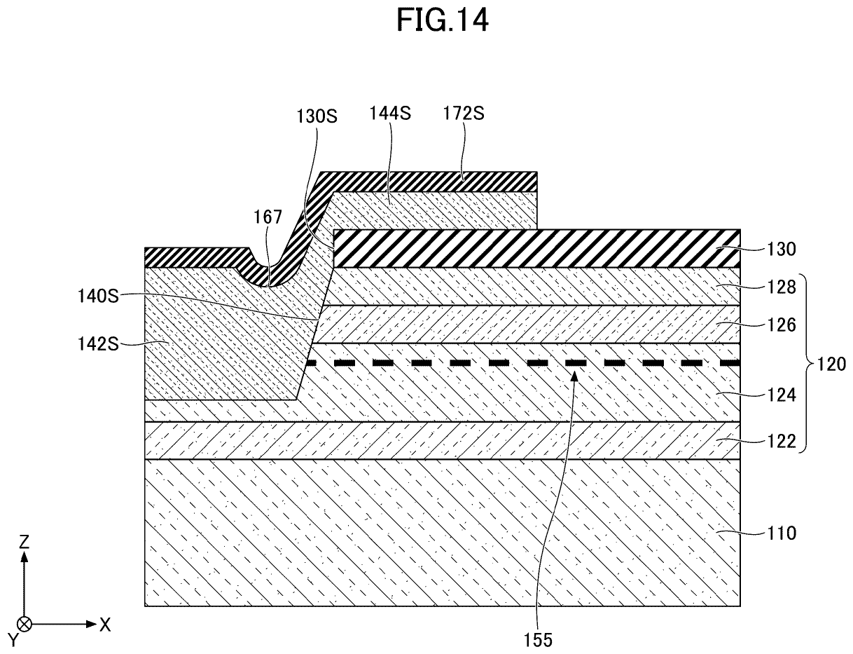

As shown in FIG. 14, when the second nitride semiconductor layer 142S is formed, the recess 167 inside the opening 130S is covered with the insulating layer 172S. Similarly, when the third nitride semiconductor layer 142D is formed, the recess 167 inside the opening 130D is covered with the insulating layer 172D.

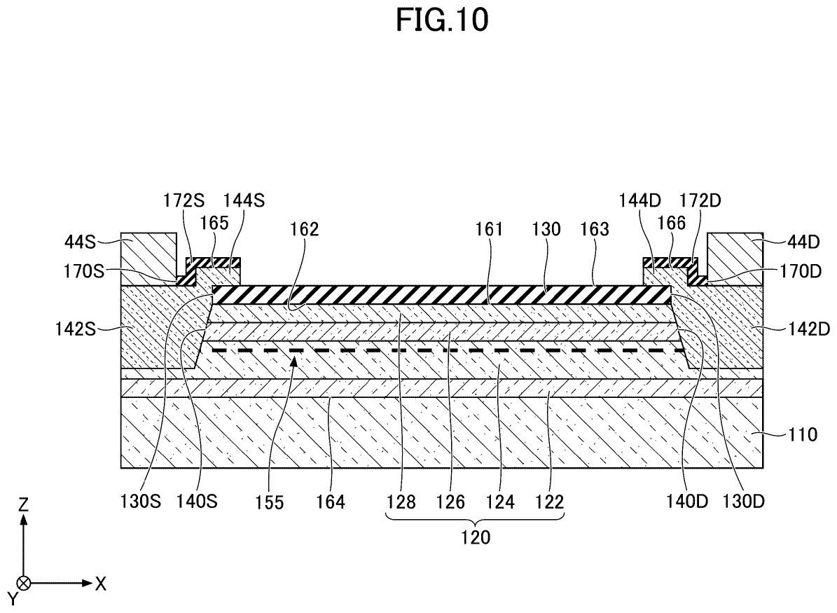

Next, as shown in FIG. 10, an opening 170S is formed in the insulating layer 172S, and an opening 170D is formed in the insulating layer 172D. The opening 170S and the opening 170D can be formed, for example, by RIE using a reactive gas containing fluorine (F). Then, the source electrode 44S is formed on the second nitride semiconductor layer 142S inside the opening 170S, and the drain electrode 44D is formed on the third nitride semiconductor layer 142D inside the opening 170D. The source electrode 44S and the drain electrode 44D can be formed, for example, by vapor deposition and lift-off. The source electrode 44S contacts the second nitride semiconductor layer 142S, and the drain electrode 44D contacts the third nitride semiconductor layer 142D.

Next, an opening 130G is formed in the insulating layer 130. The opening 130G can be formed, for example, by RIE using a reactive gas containing fluorine (F). Then, the gate electrode 50 is formed on the insulating layer 130 (see FIG. 1), making Schottky contact with the first nitride semiconductor layer 120 through the opening 130G.

With this approach, the nitride semiconductor device 100 according to the embodiment can be manufactured.

In the present embodiment, the second nitride semiconductor layer 142S has the first covering portion 144S, and the third nitride semiconductor layer 142D has the second covering portion 144D. In this arrangement, the removal (wet etching) of a portion of the fourth nitride semiconductor layer 142 to form the second nitride semiconductor layer 142S and the third nitride semiconductor layer 142D is completed before the opening 130S and the opening 130D are exposed. In this case, the etchant such as TMAH used for wet etching does not reach the sidewall surfaces of the opening 130S and the opening 130D.

If the etchant reaches the sidewall surface of the opening 130S and the sidewall surface of the opening 130D, a portion with low crystallinity in proximity to the recess 167 may be slightly etched. If a portion of the second nitride semiconductor layer 142S with low crystallinity is slightly etched, the cap layer 128 and the barrier layer 126 may be etched depending on the shape and size of the recess 167 in the ZX cross-sectional view. Similarly, if a portion of the third nitride semiconductor layer 142D with low crystallinity is slightly etched, the cap layer 128 and the barrier layer 126 may be etched depending on the shape and size of the recess 167 in the ZX cross-sectional view. In addition, the degree of etching of the barrier layer 126 becomes non-uniform along the Y-axis direction. In this case, the concentration of the 2DEG becomes non-uniform along the Y-axis direction, and the current tends to concentrate in a portion with high concentration of the 2DEG and low electrical resistance. As a result, the breakdown voltage might be decreased.

In the present embodiment, as described above, the etchant does not reach the sidewall surfaces of the opening 130S and the opening 130D, and the etchant does not contact the first nitride semiconductor layer 120. As a result, the cap layer 128, the barrier layer 126, and the channel layer 124 are not etched, and high breakdown voltage for the nitride semiconductor device 100 is obtained.

Since the distance of the upper surface 165 from the lower surface 164 is greater than the reference distance L0 between the upper surface 161 and the lower surface 164 of the first nitride semiconductor layer 120, etching of the barrier layer 126 and the channel layer 124 in proximity to the second nitride semiconductor layer 142S can be easily prevented. When the distance of the upper surface 166 from the lower surface 164 is greater than the reference distance L0 between the upper surface 161 and the lower surface 164 of the first nitride semiconductor layer 120, etching of the barrier layer 126 and the channel layer 124 in proximity to the third nitride semiconductor layer 142D can be easily prevented.

A distance L1 between the upper surface 163 and the upper surface 165 is, for example, greater than or equal to 10 nm and less than or equal to 100 nm. When the distance L1 is set to 10 nm or greater, etching of the barrier layer 126 and the channel layer 124 in proximity to the second nitride semiconductor layer 142S can be easily prevented. When the distance L1 is set to 100 nm or less, excessive steps associated with the first covering portion 144S can be easily prevented. The distance L1 may be greater than or equal to 20 nm and less than or equal to 90 nm, and may be greater than or equal to 30 nm and less than or equal to 80 nm.

A distance L2 between the upper surface 163 and the upper surface 166 is, for example, greater than or equal to 10 nm and less than or equal to 100 nm. When the distance L2 is set to 10 nm or greater, etching of the barrier layer 126 and the channel layer 124 in proximity to the third nitride semiconductor layer 142D can be easily prevented. When the distance L2 is set to 100 nm or less, excessive steps associated with the second covering portion 144D can be easily prevented. The distance L2 may be greater than or equal to 20 nm and less than or equal to 90 nm, and may be greater than or equal to 30 nm and less than or equal to 80 nm.

By use of the first nitride semiconductor layer 120 having the cap layer 128 with the upper surface 161, the barrier layer 126 can be protected from damage caused by plasma or the like that is generated in a manufacturing process of the nitride semiconductor device 100.

A length W1 of the first covering portion 144S in the X-axis direction is, for example, greater than or equal to 50 nm and less than or equal to 300 nm. When the length W1 is set to 50 nm or greater, etching of the barrier layer 126 and the channel layer 124 in proximity to the second nitride semiconductor layer 142S can be easily prevented. The length W1 is the length in the X-axis direction of a portion where the first covering portion 144S contacts the upper surface 163 of the insulating layer 130, and does not include the length in the X-axis direction of a portion where the first covering portion 144S does not contact the upper surface 163 of the insulating layer 130. The length W1 can be set independently of the distance L1 between the upper surface 163 and the upper surface 165. When the length W1 is set to 300 nm or less, a short circuit between the gate electrode 50 and the second nitride semiconductor layer 142S can be easily prevented. The length W1 may be greater than or equal to 70 nm and less than or equal to 280 nm, and may be greater than or equal to 100 nm and less than or equal to 250 nm.

A length W2 of the second covering portion 144D in the X-axis direction is, for example, greater than or equal to 50 nm and less than or equal to 300 nm. When the length W2 is set to 50 nm or greater, etching of the barrier layer 126 and the channel layer 124 in proximity to the third nitride semiconductor layer 142D can be easily prevented. The length W2 is the length in the X-axis direction of a portion where the second covering portion 144D contacts the upper surface 163 of the insulating layer 130, and does not include the length in the X-axis direction of a portion where the second covering portion 144D does not contact the upper surface 163 of the insulating layer 130. The length W2 can be set independently of the distance L2 between the upper surface 163 and the upper surface 166. When the length W2 is set to 300 nm or less, a short circuit between the gate electrode 50 and the third nitride semiconductor layer 142D can be easily prevented. The length W2 may be greater than or equal to 70 nm and less than or equal to 280 nm, and may be greater than or equal to 100 nm and less than or equal to 250 nm. The lengths W1 and W2 may be equal to each other, or may be different from each other.

When the electrical resistance of the second nitride semiconductor layer 142S and the electrical resistance of the third nitride semiconductor layer 142D are lower than the electrical resistance of the channel region 155, the electrical resistance between the source electrode 44S and the drain electrode 44D can be reduced.

When the second nitride semiconductor layer 142S and the third nitride semiconductor layer 142D contain n-type impurities, low electrical resistance for the second nitride semiconductor layer 142S and the third nitride semiconductor layer 142D can be easily obtained. The n-type impurities are not limited to germanium (Ge), and may be silicon (Si). The concentration of the n-type impurities is, for example, 1×10²⁰ cm⁻³ or more. When the concentration of the n-type impurities is 1×10²⁰ cm⁻³ or more, the second nitride semiconductor layer 142S and the third nitride semiconductor layer 142D can easily obtain particularly low electrical resistance. The concentration of the n-type impurities may be 5×10²⁰ cm⁻³ or more, and may be 1×10²¹ cm⁻³ or more. The second nitride semiconductor layer 142S and the third nitride semiconductor layer 142D, each having the concentration of the n-type impurities of 1×10²⁰ cm⁻³ or more, can be formed by, for example, sputtering, but it is difficult to form the above nitride semiconductor layers by MOCVD. The concentration of the n-type impurities can be measured by secondary ion mass spectrometry (SIMS).

When the second nitride semiconductor layer 142S is provided in the first recess 140S and the third nitride semiconductor layer 142D is provided in the second recess 140D, the second nitride semiconductor layer 142S and the third nitride semiconductor layer 142D can be easily formed.

The insulating layer 130 is provided on the upper surface 161, such that the insulating layer 130 contacts the first covering portion 144S and the second covering portion 144D. In this arrangement, the first nitride semiconductor layer 120 can be protected by the insulating layer 130.

Although the above embodiments have been described in detail, the present disclosure is not limited to specific embodiment(s), and various modifications and changes can be made within the scope of the present disclosure.

What is claimed is:

1. A nitride semiconductor device comprising:
a first nitride semiconductor layer including a channel layer and a barrier layer that overlap each other along a first axis, the first nitride semiconductor layer having a first surface intersecting the first axis;
an insulating layer provided on the first surface, and having a second surface facing the first surface and a third surface opposite the second surface;
a second nitride semiconductor layer; and
a third nitride semiconductor layer,
wherein the channel layer and the barrier layer are interposed between the second nitride semiconductor layer and the third nitride semiconductor layer along a second axis intersecting the first axis, and
wherein in a cross-sectional view including the first axis and the second axis,
the second nitride semiconductor layer includes a first covering portion covering a portion of the third surface, and
the third nitride semiconductor layer includes a second covering portion covering a portion of the third surface.

2. The nitride semiconductor device according to claim 1, wherein the first nitride semiconductor layer has a fourth surface opposite the first surface,
wherein the first covering portion has a fifth surface disposed at a distance from the fourth surface that is greater than a reference distance between the first surface and the fourth surface, and
wherein the second covering portion has a sixth surface disposed at a distance from the fourth surface that is greater than the reference distance.

3. The nitride semiconductor device according to claim 2, wherein a distance between the third surface and the fifth surface is greater than or equal to 10 nm and less than or equal to 100 nm, and
wherein a distance between the third surface and the sixth surface is greater than or equal to 10 nm and less than or equal to 100 nm.

4. The nitride semiconductor device according to claim 1, wherein the first covering portion and the second covering portion include polycrystalline material.

5. The nitride semiconductor device according to claim 1, wherein the first nitride semiconductor layer includes a cap layer having the first surface.

6. The nitride semiconductor device according to claim 1, wherein a length of the first covering portion in a direction along the second axis is greater than or equal to 50 nm and less than or equal to 300 nm, and
wherein a length of the second covering portion in the direction along the second axis is greater than or equal to 50 nm and less than or equal to 300 nm.

7. The nitride semiconductor device according to claim 1, wherein the channel layer includes a channel region including two-dimensional electron gas, and
wherein electrical resistance of the second nitride semiconductor layer and electrical resistance of the third nitride semiconductor layer are both lower than electrical resistance of the channel region.

8. The nitride semiconductor device according to claim 1, wherein each of the second nitride semiconductor layer and the third nitride semiconductor layer includes an n-type impurity.

9. The nitride semiconductor device according to claim 8, wherein concentration of the impurity is 1×10²⁰ cm⁻³ or more.

10. The nitride semiconductor device according to claim 1, wherein the first nitride semiconductor layer includes a first recess and a second recess such that the channel layer and the barrier layer are interposed between the first recess and the second recess along the second axis,
wherein the second nitride semiconductor layer is provided in the first recess, and
wherein the third nitride semiconductor layer is provided in the second recess.

11. A method for manufacturing a nitride semiconductor device comprising:
providing a first nitride semiconductor layer including a channel layer and a barrier layer that overlap along a first axis, the first nitride semiconductor layer having a first surface;
forming, on the first surface, a first insulating layer having a second surface facing the first surface and a third surface opposite the second surface;
forming a first opening and a second opening in the first insulating layer, such that the channel layer and the barrier layer are interposed between the first opening and the second opening along a second axis intersecting the first axis, in a plan view;
forming, in the first nitride semiconductor layer, a first recess connected to the first opening, and a second recess connected to the second opening;
forming, by sputtering, a fourth nitride semiconductor layer in the first recess and the first opening, in the second recess and the second opening, and on the first insulating layer, the fourth nitride semiconductor layer including polycrystalline material on the first insulating layer;
forming, on the fourth nitride semiconductor layer,
a second insulating layer covering both a portion of the fourth nitride semiconductor layer in the first recess and the first opening, and a portion of the fourth nitride semiconductor layer located on a portion of the first insulating layer, and
a third insulating layer covering both a portion of the fourth nitride semiconductor layer in the second recess and the second opening, and a portion of the fourth nitride semiconductor layer located on a portion of the first insulating layer; and
removing a portion of the fourth nitride semiconductor layer that is not covered by the second insulating layer and the third insulating layer to form:
a second nitride semiconductor layer including a first covering portion covering a portion of the third surface, and
a third nitride semiconductor layer including a second covering portion covering a portion of the third surface.
